(19) United States
(12) Patent Application Publication
(10) Pub. No.: US 2010/0301687 A1
(43) Pub. Date: Dec. 2, 2010

(54) MOLDED MOTOR, ELECTRIC MOTOR VEHICLE AND METHOD OF MANUFACTURING MOLDED MOTOR

(75) Inventors: Takeshi Nagao, Osaka (JP); Kenji Taguchi, Osaka (JP); Hiroaki Sagara, Kasai-City (JP); Tetsuji Ueta, Osaka (JP); Takashi Uchino, Osaka (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/748,760

(22) Filed: Mar. 29, 2010

(30) Foreign Application Priority Data
May 29, 2009 (JP) 2009-131574

(51) Int. Cl. H02K 1/06; H05K 13/00

(52) U.S. Cl. 310/43; 29/592.1

(57) ABSTRACT

In a molded motor, a driving shaft is protruded from a motor case. A stator includes a molded portion forming the end face of the stator. The molded portion includes a groove portion provided in the end face of the stator. The motor case includes a protruding portion protruded toward the end face of the stator. The protruding portion, fitted into the groove portion, is made of a material having a heat conductivity higher than the molded portion.

### CROSS REFERENCE TO RELATED APPLICATIONS

This application is based upon and claims the benefit of priority from prior Japanese Patent Application No. 2009-131574, filed on May 29, 2009; the entire contents of which are incorporated herein by reference.

### BACKGROUND OF THE INVENTION

1. Field of the Invention

The present invention relates to a molded motor including a resin-molded stator, an electric motor vehicle, and a method of manufacturing the molded motor.

2. Description of the Related Art

Conventionally, a molded motor has been widely used as a driving source for an electric motor vehicle, a washing machine or the like. The molded motor includes: a resin-molded stator of columnar shape; a first motor case provided on one end face of the stator; a second motor case provided on the other end face of the stator; and a drive shaft rotatably supported by the first motor case and protruded from the first motor case. The stator includes a molded portion in which multiple teeth annually arranged and coils respectively wound around the teeth are molded.

There is proposed a technique in which ribs protruding into a molded portion are formed on the second motor case (see Japanese Patent Application Publication No. 2007-60834). With this technique, heat generated from the coils can be efficiently transmitted to the second motor case via the ribs. This makes it possible to improve the heat radiation on the second-motor-case side of the stator.

Meanwhile, the first motor case, which includes the drive shaft protruded from the first motor case, is directly subjected to torque of the rotating drive shaft, while the second motor case is not directly subjected to the torque of the rotating drive shaft. For this reason, the first motor case needs to have a higher strength than the second motor case has, so as to withstand the torque of the drive shaft.

However, in order for the first motor case to have the higher strength, the first motor case needs to have a larger size and thickness than the second motor case, for example. However, this causes a problem of deteriorating the heat radiation on one of the motor-case sides of the stator, from a side where the drive shaft protruded.

### SUMMARY OF THE INVENTION

A molded motor of first aspect includes: a stator of columnar shape; a motor case provided on an end face of the stator; and a drive shaft rotatably supported by the motor case and configured to give a driving force to a load. The drive shaft is protruded from the motor case. The stator includes a molded portion forming the end face of the stator. The molded portion includes a groove portion provided in the end face of the stator. The motor case includes a protruding portion protruded toward the end face of the stator. The protruding portion, fitted into the groove portion, is made of a material having heat conductivity higher than the molded portion.

According to the molded motor of the first aspect, heat generated by the coils of the stator can be efficiently transmitted to the motor case via the protruding portion having heat conductivity higher than the molded portion. This improves the heat radiation of the stator, on the motor-case sides where the driving shaft is protruded.

In the first aspect, the groove portion extends in a circumferential direction of the stator.

In the first aspect, the stator includes a plurality of teeth and coils respectively wound around the plurality of teeth. The groove portion is formed at a same position as that of each coil in a radial direction of the stator.

In the first aspect, the groove portion extends in a radial direction of the stator.

An electric motor vehicle of a second aspect includes a drive wheel; and the molded motor of the first aspect configured to drive the drive wheel.

A method of manufacturing a molded motor of the third aspect includes following steps. The molded motor includes a stator of columnar shape, a motor case provided on an end face of the stator, and a drive shaft rotatably supported by the motor case and configured to give a driving force to a load. The method includes: a step A of forming the stator including a molded portion forming the end face by molding a plurality of teeth arranged annularly with a resin material; and a step B of placing the motor case on the end face of the stator so that the drive shaft is protruded from the motor case. In the step A, a groove portion is formed in the end face of the stator. In the step B, a protruding portion formed on the motor case is fitted into the groove portion, the protruding portion is protruded toward the end face of the stator and being made of a material having a heat conductivity higher than the molded portion.

### BRIEF DESCRIPTION OF THE DRAWINGS

FIG. 1 is a right side view of an electric motorcycle 100 according to a first embodiment of the present invention.

FIG. 2 is a cross sectional view taken along the A-A line of FIG. 1.

FIG. 3 is a perspective view showing an assembly state of a molded motor 10 according to the first embodiment of the present invention.

FIG. 4 is a plan view of the molded motor 10 according to the first embodiment of the present invention, as viewed from an output side of the molded motor 10.

FIG. 5 is a side view of the molded motor 10 according to the first embodiment of the present invention.

FIG. 6 is a plan view of the molded motor 10 according to the first embodiment of the present invention, as viewed from a non-output side of the molded motor 10.

FIG. 7 is a view for explaining a structure of a stator 12 according to the first embodiment of the present invention.

FIG. 8 is a view for explaining a structure of a first motor case 13 according to the first embodiment of the present invention.

FIG. 9 is a cross sectional view taken along the B-B line of FIG. 4.

FIG. 10 is a view for explaining a structure of a stator 12 according to a second embodiment of the present invention.

FIG. 11 is a cross sectional view taken along the C-C line of FIG. 10.

### DETAILED DESCRIPTION OF THE EMBODIMENTS

Embodiments of the present invention will be described with reference to the drawings. Note that, in the following description of the drawings, same or similar reference signs denote same or similar elements and portions. In addition, it should be noted that the drawings are schematic and ratios of dimensions and the like are different from actual ones. Therefore, specific dimensions and the like should be determined in consideration of the following description. Moreover, the drawings also include portions having different dimensional relationships and ratios from each other.

### First Embodiment

(Outline Structure of Electric Motor Vehicle)

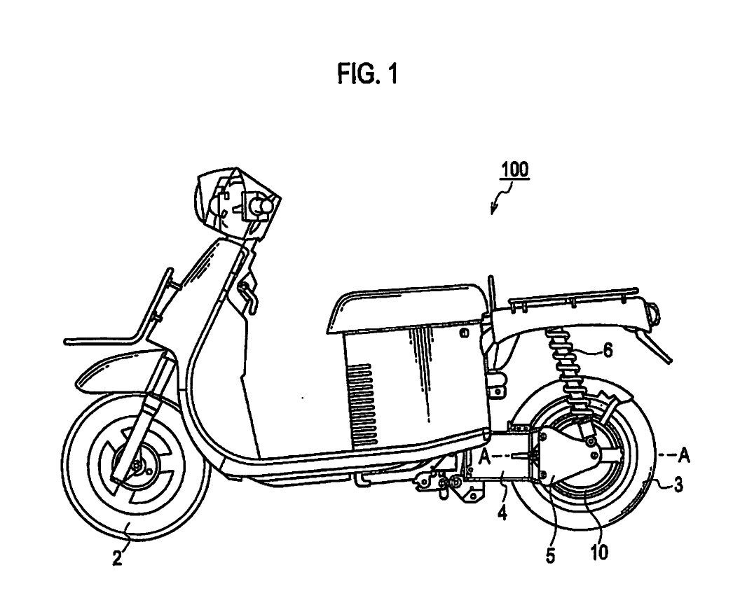

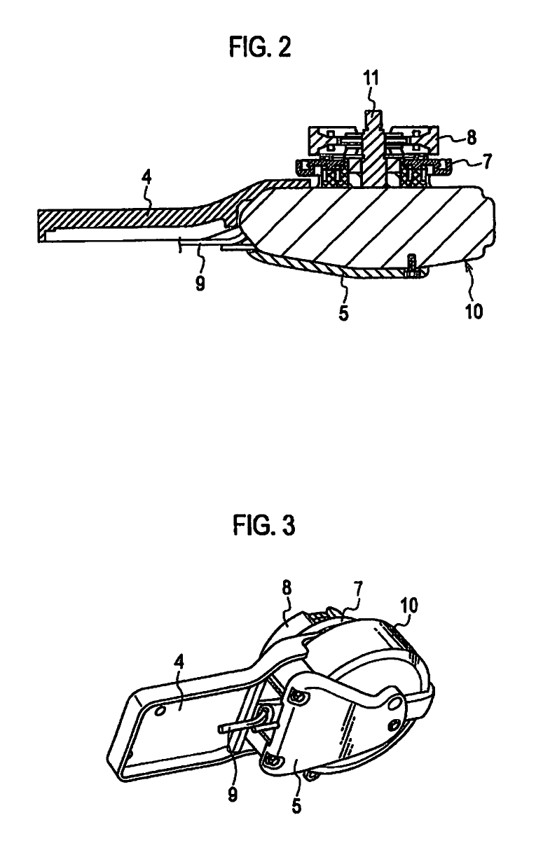

Hereinbelow, an electric motorcycle 100 will be described with reference to the drawings, the electric motorcycle 100 being an electric motor vehicle to which a molded motor 10 according to First Embodiment of the present invention is applied. FIG. 1 is a right side view of the electric motorcycle 100. FIG. 2 is a cross sectional view taken along the A-A line of FIG. 1. FIG. 3 is a perspective view showing an assembly state of the molded motor 10. Note that FIGS. 2 and 3 show a structure of only components near the molded motor 10.

As shown in FIG. 1, the electric motorcycle 100 is a so-called under-bone type electric motorcycle, in which a body frame (not shown) is provided on a lower side of the electric motorcycle 100. The electric motorcycle 100 includes a front wheel 2, a rear wheel 3, a swing arm 4, a suspension case 5, a rear suspension 6 and the molded motor 10.

As shown in FIG. 1, the front wheel 2 is rotatably supported by a front fork. The rear wheel 3 is rotatably supported by the molded motor 10. The rear wheel 3 is an example of a “load” according to the present invention. The swing arm 4 is swingably attached to the body frame.

As shown in FIG. 1, the suspension case 5 is coupled to a rear end portion of the swing arm 4 and the molded motor 10. The rear suspension 6 is coupled to the suspension case 5 and the body frame.

As shown in FIGS. 2 and 3, the molded motor 10 is fixed to the rear end portion of the swing arm 4 and the suspension case 5 in such a manner as to be sandwiched therebetween. A driving force of the molded motor 10 is transmitted to the rear wheel 3 via a motor shaft 11. A brake back plate 7 and a brake 8 are provided between the rear wheel 3 and the molded motor 10. The brake back plate 7 is fixed to the molded motor 10 (specifically, a first motor case 13 to be described later). The structure of the molded motor 10 will be described later.

Incidentally, a motor power line 9 for supplying power to the molded motor 10 is provided to a front portion of the molded motor 10.

(Outline Structure of Molded Motor)

Next, an outline structure of the molded motor 10 according to First Embodiment will be described with reference to the drawings. Note that in the following, an “output side” is a rear wheel 3 side of the molded motor 10, while a “non-output side” is an opposite side of the molded motor 10 from the output side.

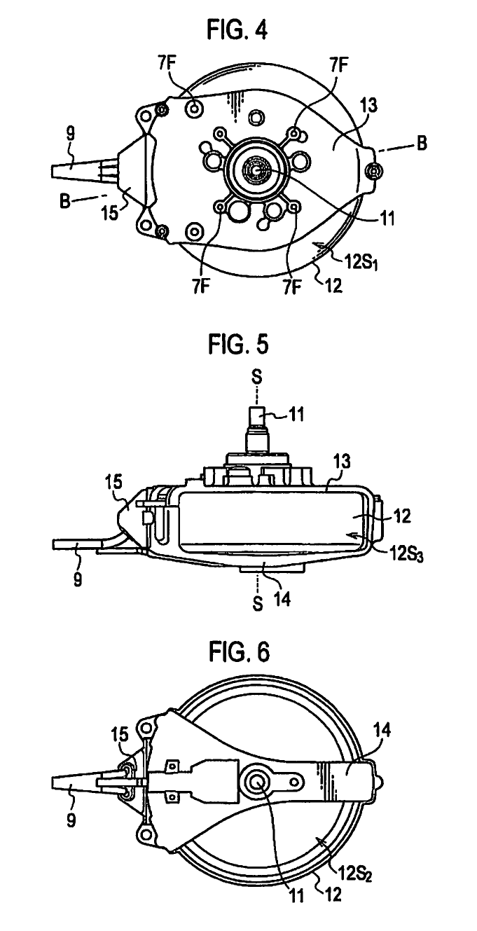

FIG. 4 is a plan view of the molded motor 10, as viewed from the output side. FIG. 5 is a side view of the molded motor 10. FIG. 6 is a plan view of the molded motor 10, as viewed from the non-output side.

As shown in FIGS. 4 to 6, the molded motor 10 includes the motor shaft 11, a stator 12, the first motor case 13, a second motor case 14 and a terminal box 15.

The motor shaft 11 rotates about a shaft axis S of the stator 12 and thereby drives the rear wheel 3. The motor shaft 11 is an example of a “drive shaft” giving a driving force to the load according to the present invention. The motor shaft 11 is provided approximately at the center of the molded motor 10 in a plan view and protruded from the first motor case 13. The motor shaft 11 is inserted into the first motor case 13, while being rotatably supported by the first motor case 13.

The stator 12 is formed into a columnar shape with the shaft axis S as the center, and has a first end face 12S₁ of the stator (hereinafter referred to as a first column-end-face 12S₁), a second end face 12S₂ of the stator (hereinafter referred to as a second column-end-face 12S₂) and an outer peripheral surface 12S₃.

The first column-end-face 12S₁ is provided on the rear wheel 3 side of the stator 12, and the motor shaft 11 is protruded from this side. The second column-end-face 12S₂ is provided on an opposite side from the first column-end-face 12S₁. The first column-end-face 12S₁ and the second column-end-face 12S₂ are each provided approximately orthogonal to the shaft axis S. The outer peripheral surface 12S₃ is continuous with the first column-end-face 12S₁ and the second column-end-face 12S₂.

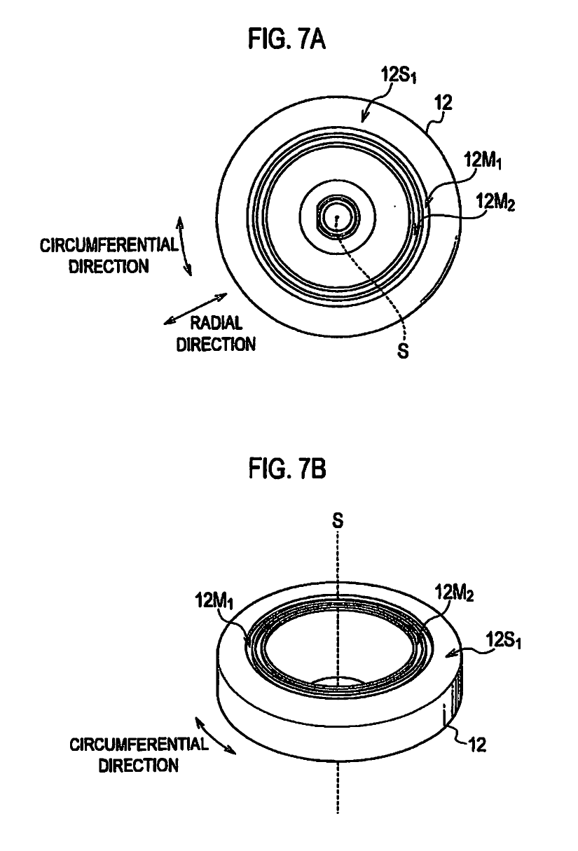

FIG. 7A and FIG. 7B are a plan view and a perspective view, respectively, of the stator 12, as viewed from a first column-end-face 12S₁ side.

As shown in FIGS. 7A and 7B, the stator 12 includes a first groove 12M₁ and a second groove 12M₂. The first groove 12M₁ and the second groove 12M₂ are provided in the first column-end-face 12S₁. In this embodiment, the first groove 12M₁ and the second groove 12M₂ are each formed into an annular shape, extending in a circumferential direction of the stator 12 with the shaft axis S as the center.

In this embodiment, as shown in FIG. 7A, the first groove 12M₁ is provided outward of the second groove 12M₂. In other words, the first groove 12M₁ surrounds the second groove 12M₂ in the plan view of the stator 12.

The first motor case 13 is provided on the first column-end-face 12S₁ of the stator 12, and rotatably supports the motor shaft 11 inserted into the first motor case 13.

In addition, the first motor case 13 is directly fixed onto the swing arm 4 and located adjacent to the rear wheel 3. The brake back plate 7 is fixed to the first motor case 13 at attaching portions 7F.

Accordingly, the first motor case 13 needs to have such a mechanical strength that the first motor case 13 can withstand torque of the rotating motor shaft 11, support the swing arm 4 and absorb a braking force to be applied in braking.

Note that, in this embodiment, the first motor case 13 is coupled to the second motor case 14 with fastening devices such as screws, the second motor case 14 formed integrally with the stator 12.

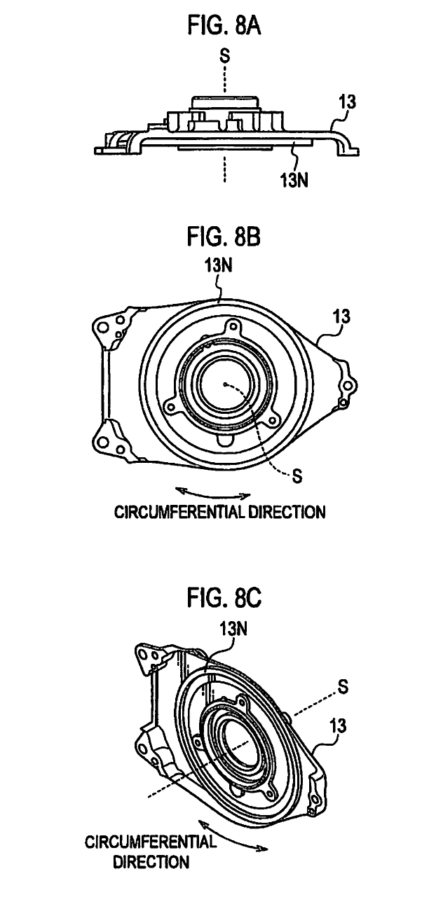

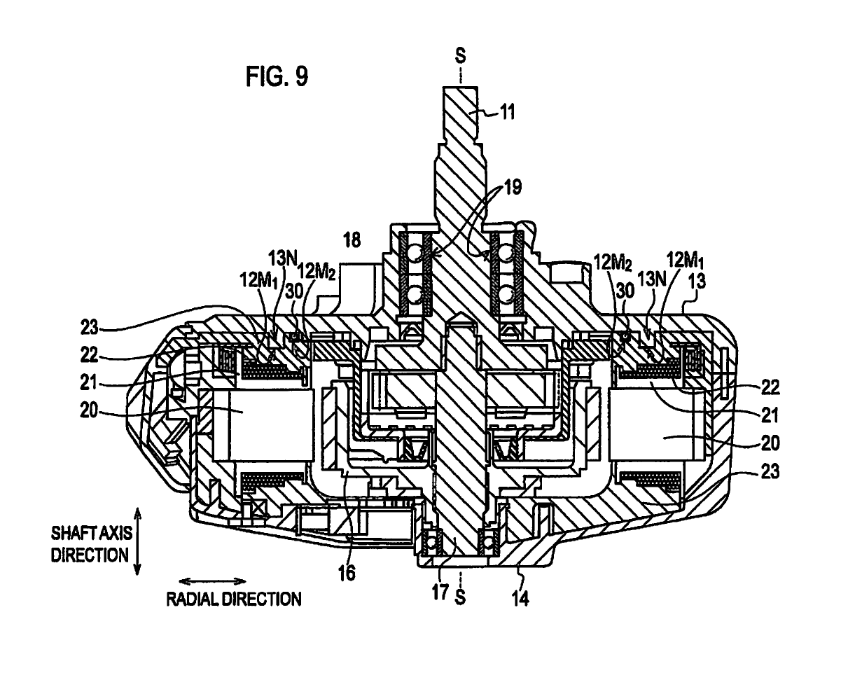

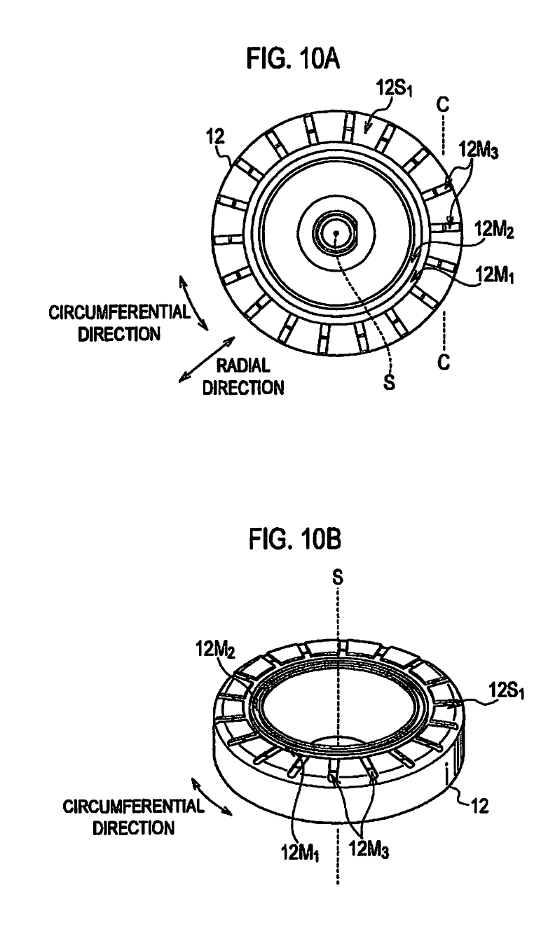

FIG. 8A is a side view of the first motor case 13. FIG. 8B and FIG. 8C are a plan view and a perspective view of the first motor case 13, respectively, as viewed from a bottom side comes to contact with the first column-end-face 12S₁.

As shown in FIGS. 8A and 8B, the first motor case 13 includes a protruding portion 13N formed on a bottom face comes to contact with contact with the first column-end-face 12S₁. When the first motor case 13 is attached to the stator 12, the protruding portion 13N protrudes toward the first column-end-face 12S₁. In this case, the protruding portion 13N is fitted into the first groove 12M₁ provided in the first column-end-face 12S₁. In this embodiment, the protruding portion 13N is formed into an annular shape, extending in the circumferential direction with the shaft axis S as the center.

Meanwhile, the protruding portion 13N is made of a material having heat conductivity higher than that of a molded portion 23 which will be described later. The protruding portion 13N and the other portion of the first motor case 13 may be made of materials different from each other. However, the entire first motor case 13 is preferably made of a material having heat conductivity higher than that of the molded portion 23.

The second motor case 14 is provided on the second column-end-face 12S₂ of the stator 12. Note that the second motor case 14 is formed integrally with the stator 12, and the swing arm 4 and the brake back plate 7 are not directly fixed to the second motor case 14. Thus, the second motor case 14 can be formed smaller and thinner than the first motor case 13.

The terminal box 15 houses the motor power line 9. In this embodiment, the terminal box 15 is attached to the second motor case 14 and the first motor case 13.

(Detailed Structure of Molded Motor)

Hereinbelow, a detailed structure of the molded motor 10 will be described with reference to the drawing. FIG. 9 is a cross sectional view taken along the B-B line of FIG. 4.

As shown in FIG. 9, the molded motor 10 includes a rotor 16, a gear shaft 17, a gear 18 and a bearing device 19. The rotor 16, the gear shaft 17 and the gear 18 are arranged inside the stator 12. The bearing device 19 is built in the first motor case 13 and rotatably supports the motor shaft 11.

The rotor 16 rotates around the shaft axis S inside the stator 12. The revolution of the rotor 16 is transmitted to the gear shaft 17 disposed along the shaft axis S. The gear 18 transmits the revolution of the rotor 16 which is thus transmitted via the gear shaft 17, to the motor shaft 11, while reducing the revolution by a predetermined reduction ratio.

The stator 12 includes multiple teeth 20, insulating members 21, coils 22 and the molded portion 23.

The multiple teeth 20 are arranged in the circumferential direction with the shaft axis S as the center. The insulating members 21 cover the outer peripheries of the teeth 20, respectively. The coils 22 are wound around the insulating members 21, respectively.

The molded portion 23 molds the teeth 20, the insulating members 21 and the coils 22. The molded portion 23 forms the first column-end-face 12S₁ and the second column-end-face 12S₂, and includes the first groove 12M₁ formed in the first column-end-face 12S₁.

Here, the protruding portion 13N of the first motor case 13 is fitted into the first groove 12M₁ formed in the first column-end-face 12S₁ of the stator 12, while an O-ring 30 is disposed and molded in the second groove 12M₂ formed in the first column-end-face 12S₁ of the stator 12. The O-ring 30 has a water-proof and dust-proof function of inhibiting moisture and dust from entering the stator 12.

In addition, the first groove 12M₁ is formed at the same position as that of each coil 22 in a radial direction of the stator 12. It should be noted that the first groove 12M₁ is away from the coils 22. With this structure, the protruding portion 13N fitted into the first groove 12M₁ and the coils 22 are electrically isolated from each other.

(Method of Manufacturing Molded Motor)

Firstly, the first motor case 13 having the protruding portion 13N thereon is manufactured.

Then, component members of the stator 12, such as the teeth 20, the insulating members 21 and the coils 22, are assembled and attached to the second motor case 14.

Then, the second motor case 14 with the component members of the stator 12 assembled and attached thereto is fitted into a lower mold.

Then, an upper mold is fitted over the multiple teeth 20, the insulating members 21 and the coils 22. The upper mold has an annular protruding portion corresponding to the first groove 12M₁.

Then, a resin material is injected between the upper mold and the lower mold.

Then, the resin material is hardened. This step forms the stator 12 which includes the molded portion 23 having the first groove 12M₁ formed therein and to which the second motor case 14 is attached integrally.

Then, the rotor 16, the gear 18 with the motor shaft 11 attached thereto, and the like are placed in the stator 12.

Lastly, while placed over the stator 12 in such a manner that the motor shaft 11 is protruded from the first motor case 13, the first motor case 13 is fixed to the second motor case 14 with screws. At this time, it is checked that the protruding portion 13N is fitted into the first groove 12M₁.

(Advantageous Effects)

In the molded motor 10 according to First Embodiment, the molded portion 23 includes the first groove 12M₁ provided in the first column-end-face 12S₁, and the first motor case 13 from which the motor shaft 11 protruded, includes the protruding portion 13N protruding toward the first column-end-face 12S₁. The protruding portion 13N is made of a material having a heat conductivity higher than that of the molded portion 23, and is fitted into the first groove 12M₁.

With the molded motor 10 according to First Embodiment, heat generated by the coils 22 can be efficiently transmitted to the first motor case 13 by the protruding portion 13N having the heat conductivity higher than that of the molded portion 23. This can improve the heat radiation on a first motor case 13 side of the stator 12, from which the motor shaft 11 projects.

In First Embodiment, in order to withstand the torque of the motor shaft 11, support the swing arm 4 and absorb the braking force to be applied in braking, the first motor case 13 from which the motor shaft 11 projects is formed larger in size and thickness than the second motor case 14 is. Thus, the stator 12 tends to have a lower heat radiation on the first motor case 13 side than on the second motor case 14 side. Accordingly, it is advantageous to improve the heat radiation on the first motor case 13 side from which the motor shaft 11 projects, as in First Embodiment.

Additionally, in First Embodiment, the first motor case 13 is disposed adjacent to the rear wheel 3. Due to this structure, air does not smoothly flow through between the rear wheel 3 and the first motor case 13 while the electric motorcycle 100 is running, and thus heat tends to stay between the rear wheel 3 and the first motor case 13. Accordingly, it is advantageous to improve the heat radiation on the first motor case 13 side from which the motor shaft 11 projects, as in First Embodiment.

Moreover, in First Embodiment, the protruding portion 13N is provided in such a manner as to extend in the circumferential direction of the stator 12. This can improve the mechanical strength of the first motor case 13. Note that the first motor case 13 needs to have such a mechanical strength that the first motor case 13 can withstand the torque of the rotating motor shaft 11, support the swing arm 4, and absorb the braking force to be applied in braking. Accordingly, it is extremely advantageous to improve the mechanical strength of the first motor case 13.

Furthermore, in First Embodiment, the first groove 12M₁ is formed at the same position as that of each coil 22 in the radial direction. Accordingly, the heat generated by the coils 22 can be efficiently transmitted from the molded portion 23 to the protruding portion 13N.

In addition, in First Embodiment, the first groove 12M₁ is provided outward of the second groove 12M₂ where the O-ring 30 is disposed, in the radial direction. This can achieve a large diameter of the protruding portion 13N as compared to a case where the first groove 12M₁ is provided inward of the second groove 12M₂. Consequently, the mechanical strength of the first motor case 13 can be improved further. In addition, the protruding portion 13N fitted into the first groove 12M₁ can inhibit moisture or the like from entering the first groove 12M₁. Consequently, this can inhibit moisture or the like from entering the stator 12 more reliably.

### Second Embodiment

Next, the molded motor 10 according to Second Embodiment of the present invention will be described with reference to the drawings. Hereinbelow, a difference from First Embodiment described above will mainly be described.

FIG. 10A and FIG. 10B are a plan view and a perspective view of the stator 12, respectively, as viewed from the first column-end-face 12S₁ side.

As shown in FIGS. 10A and 10B, in Second Embodiment, the stator 12 includes multiple third grooves 12M₃ in addition to the first groove 12M₁ and the second groove 12M₂.

The multiple third grooves 12M₃ are provided radially in the first column-end-face 12S₁ with the shaft axis S as the center. This means that each of the multiple third grooves 12M₃ is provided in such a manner as to extend in the radial direction of the stator 12 with the shaft axis S as the center.

Although not shown, multiple protruding portions 13N formed radially on the bottom face of the first motor case 13 are fitted into the multiple third grooves 12M₃, respectively. The first motor case 13 is attached to the second motor case 14 with fastening devices such as screws, while the multiple protruding portions 13N are fitted into the respective multiple third grooves 12M₃.

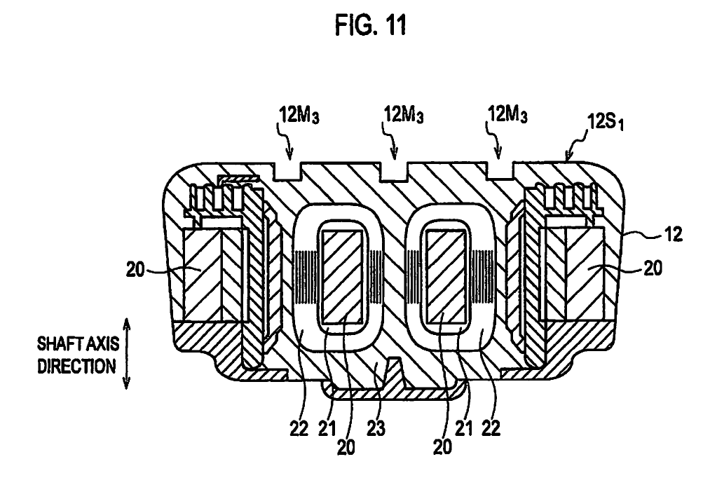

FIG. 11 is a cross sectional view taken along the C-C line of FIG. 10. As shown in FIG. 11, each of the third grooves 12M₃ is formed above a gap between each adjacent two of the teeth 20 in a shaft axis direction of the stator 12. In other words, the third groove 12M₃ is formed at the same position as that of the gap between the two teeth 20 in the circumferential direction of the stator 12.

(Advantageous Effects)

In the molded motor 10 according to Second Embodiment, each of the third grooves 12M₃ is provided in such a manner as to extend in the radial direction, while being formed at the same position as that of the gap between the two adjacent teeth 20 in the circumferential direction.

Accordingly, it is possible to form the third grooves 12M₃ deeply and to thus have large contact areas between the protruding portions 13N and the molded portion 23. Consequently, the heat radiation on a drive wheel side of the stator 12 can be improved further.

Meanwhile, the first motor case 13 is attached to the second motor case 14 with the multiple protruding portions 13N fitted into the respective multiple third grooves 12M₃. Accordingly, the multiple third grooves 12M₃ can be utilized for determining the attaching position of the first motor case 13.

### Other Embodiments

The present invention has been disclosed by using the foregoing embodiments. However, it should not be understood that the description and drawings which constitute part of this disclosure limit the present invention. From this disclosure, various alternative embodiments, examples, and operation techniques will be easily found by those skilled in the art.

For example, in the foregoing embodiments, the second groove 12M₂ is provided in the first column-end-face 12S₁. However, the second groove 12M₂ does not have to be provided. Even in this case, the water-proof and dust-proof function provided for the inside of the stator 12 can be ensured by the protruding portion 13N fitted into the first groove 12M₁. Note that the water-proof and dust-proof function provided for the inside of the stator 12 can be ensured more sufficiently by inserting a liquid gasket or the like between an inner wall of the first groove 12M₁ and the protruding portion 13N.

In the foregoing embodiments, the rear wheel 3 is taken as an example of the “load” to describe the case where the molded motor 10 is applied to the electric motorcycle 100. However, the “load” is not limited to this. For example, the molded motor 10 can be applied to a washing machine. In this case, a washing machine tub provided in the washing machine corresponds to the “load” according to the present invention.

In the foregoing embodiments, the motor shaft 11 is taken as an example of the “drive shaft” to describe the case where the molded motor 10 is applied to the electric motorcycle 100. However, the “drive shaft” is not limited to this. For example, when the electric motorcycle 100 does not include the gear 18, the gear shaft 17 may be protruded from the first motor case 13 and may be rotatably supported by the first motor case 13. In this case, the gear shaft 17 corresponds to the “drive shaft” according to the present invention.

In First Embodiment described above, the first groove 12M₁ and the protruding portion 13N are formed into an annular shape. However, the shape is not limited to this. The first groove 12M₁ and the protruding portion 13N do not have to be continuous but may be broken halfway. In addition, the first groove 12M₁ and the protruding portion 13N do not have to be formed linearly but may be formed in zigzags. Note that, when the first groove 12M₁ is broken halfway, the first groove 12M₁ can be utilized for determining the attaching position of the first motor case 13.

In Second Embodiment described above, each of the third grooves 12M₃ is formed at the same position as that of the gap between the two adjacent teeth 20 in the radial direction. However, the position is not limited to this. The third groove 12M₃ may be formed at the same position as that of each coil 22 in the radial direction. In this case, the protruding portion 13N fitted into the third groove 12M₃ can efficiently absorb heat from the coil 22.

In Second Embodiment described above, the multiple third grooves 12M₃ are formed in addition to the first groove 12M₁. However, the first groove 12M₁ does not have to be formed.

As described above, it is to be understood that the present invention includes various embodiments which are not described herein. Accordingly, the present invention should be determined only by the matters to define the invention in the scope of claims regarded as appropriate based on the description.

What is claimed is:

1. A molded motor comprising:
a stator of columnar shape;
a motor case provided on an end face of the stator; and
a drive shaft rotatably supported by the motor case and configured to give a driving force to a load, wherein
the drive shaft is protruded from the motor case,
the stator includes a molded portion forming the end face of the stator,
the molded portion includes a groove portion provided in the end face of the stator,
the motor case includes a protruding portion protruded toward the end face of the stator, and
the protruding portion, fitted into the groove portion, is made of a material having a heat conductivity higher than the molded portion.

2. The molded motor according to claim 1, wherein the groove portion extends in a circumferential direction of the stator.

3. The molded motor according to claim 2, wherein
the stator includes a plurality of teeth and coils respectively wound around the plurality of teeth, and
the groove portion is formed at a same position as that of each coil in a radial direction of the stator.

4. The molded motor according to claim 1, wherein the groove portion extends in a radial direction of the stator.

5. The molded motor according to claim 2, wherein the groove portion extends in a radial direction of the stator.

6. The molded motor according to claims 3, wherein the groove portion extends in a radial direction of the stator.

7. An electric motor vehicle comprising:
a drive wheel; and
the molded motor according to claim 1 configured to drive the drive wheel.

8. A method of manufacturing a molded motor including a stator of columnar shape, a motor case provided on an end face of the stator, and a drive shaft rotatably supported by the motor case and configured to give a driving force to a load, the method comprising:
a step A of forming the stator including a molded portion forming the end face by molding a plurality of teeth arranged annularly with a resin material; and
a step B of placing the motor case on the end face of the stator so that the drive shaft is protruded from the motor case, wherein
in the step A, a groove portion is formed in the end face of the stator, and
in the step B, a protruding portion formed on the motor case is fitted into the groove portion, the protruding portion being protruded toward the end face of the stator and being made of a material having a heat conductivity higher than the molded portion.
